(19) United States
(12) Patent Application Publication
(10) Pub. No.: US 2012/0211762 A1
(43) Pub. Date: Aug. 23, 2012

(54) SEMICONDUCTOR DEVICE, METHOD OF MANUFACTURING SEMICONDUCTOR DEVICE AND ELECTRONIC CIRCUIT

(75) Inventors: Tadahiro IMADA, Kawasaki (JP); Keishiro Okamoto, Kawasaki (JP); Nobuhiro Imaizumi, Kawasaki (JP); Toshihide Kikkawa, Kawasaki (JP)

(73) Assignee: FUJITSU LIMITED, Kawasaki (JP)

(21) Appl. No.: 13/334,766

(22) Filed: Dec. 22, 2011

(30) Foreign Application Priority Data
Feb. 23, 2011 (JP) 2011-037533

(51) Int. Cl. H01L 29/778; H01L 21/56; H01L 23/48; H01L 29/20

(52) U.S. Cl. 257/76; 257/194; 438/123; 257/734; 257/E29.089; 257/E29.246; 257/E21.502; 257/E23.011

(57) ABSTRACT

A semiconductor device includes: a semiconductor chip having an electrode; a lead corresponding to the electrode; a metal line coupling the electrode to the lead; a first resin portion covering a coupling portion between the metal line and the electrode and a coupling portion between the metal line and the lead; and a second resin portion covering the metal line, the first resin portion, and the semiconductor chip.

### CROSS-REFERENCE TO RELATED APPLICATIONS

This application claims the benefit of priority from Japanese Patent Application No. 2011-37533 filed on Feb. 23, 2011, the entire contents of which are incorporated herein by reference.

### FIELD

The embodiments discussed herein relate to a semiconductor device and a method of manufacturing a semiconductor device.

### BACKGROUND

GaN, AlN, and InN included in Nitride semiconductors, and materials including a mixed crystal of these nitride semiconductors have a wide band-gap and are used in high-output electronic devices, short-wavelength light-emitting devices, and the like. Field-effect transistors (FETs), for example, high electron mobility transistors (HEMTs) are used in high-output electronic devices. HEMTs including a nitride semiconductor are used in high-output and high-efficiency amplifiers, high-power switching devices, and the like. In an HEMT including AlGaN serving an electron supply layer and GaN serving an electron transit layer, distortion due to a difference in a lattice constant between AlGaN and GaN causes piezoelectric polarization in AlGaN. Accordingly, a high-concentration two-dimensional electron gas is generated, and thus characteristics of the HEMT may be improved.

The band-gap of GaN used in an HEMT including a nitride semiconductor may be 3.4 eV, which is larger than the band-gap of Si, i.e., 1.1 eV and the band-gap of GaAs, i.e., 1.4 eV. Therefore, the HEMT may operate at a high voltage. A gate electrode, a source electrode, and a drain electrode that are formed on a surface of a semiconductor substrate of such an HEMT are coupled to a lead frame or the like via wire bonding.

For example, Japanese Laid-open Patent Publication No. 2010-21347 discloses the related art.

### SUMMARY

According to one aspects of the embodiments, a semiconductor device includes: a semiconductor chip having an electrode; a lead corresponding to the electrode; a metal line coupling the electrode to the lead; a first resin portion covering a coupling portion between the metal line and the electrode and a coupling portion between the metal line and the lead; and a second resin portion covering the metal line, the first resin portion, and the semiconductor chip.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary semiconductor device;

FIG. 2 illustrates an exemplary top surface of a semiconductor chip,

FIGS. 3A to 3E illustrate an exemplary method for manufacturing a semiconductor chip;

FIGS. 4A to 4F illustrate an exemplary method for manufacturing a semiconductor device;

FIG. 5 illustrates an exemplary semiconductor device;

FIGS. 6A to 6F illustrate an exemplary method of manufacturing a semiconductor device;

FIG. 7 illustrates an exemplary power supply circuit; and

FIG. 8 illustrates an exemplary high-frequency amplifier.

### DESCRIPTION OF EMBODIMENTS

A high voltage is applied to an electrode of, for example, a high-breakdown voltage power device that operates at a high voltage. Therefore, a high-voltage current flows through a bonding wire for applying a voltage to the electrode. A leakage current may increase because the difference in potential between bonding wires increases when the distance between adjacent bonding wires is decreased.

When sealing is performed with a molding resin for a high breakdown voltage, the molding resin having a high viscosity, bonding wires are pressed by a force applied to the molding resin, and the shapes of the bonding wires may be changed. Therefore, the distance between adjacent bonding wires may be deceased. Furthermore, the bonding wires are pressed by a force applied to the molding resin, and may be detached from coupling portions such as electrodes.

With the realization of a low-resistance bonding wire, the material of the bonding wire may include copper. When the material of the bonding wire includes copper, copper and other materials may be oxidized since sealing with a molding resin material does not provide sufficient moisture resistance.

Substantially the same components, similar components, and the like are assigned the same reference numerals, and the description of those components may be omitted or reduced.

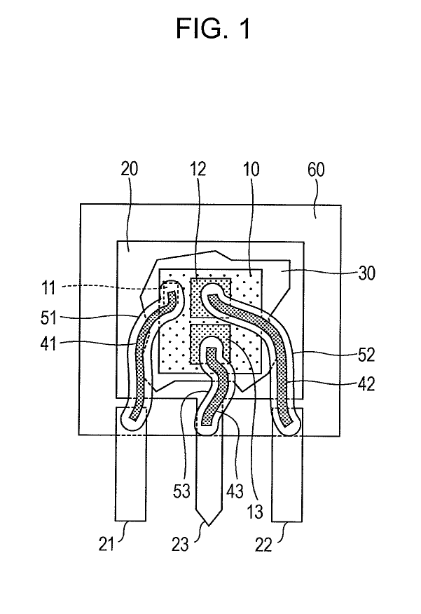

FIG. 1 illustrates an exemplary semiconductor device. The semiconductor device may include a semiconductor chip on which a discrete-packaged HEMT transistor is formed.

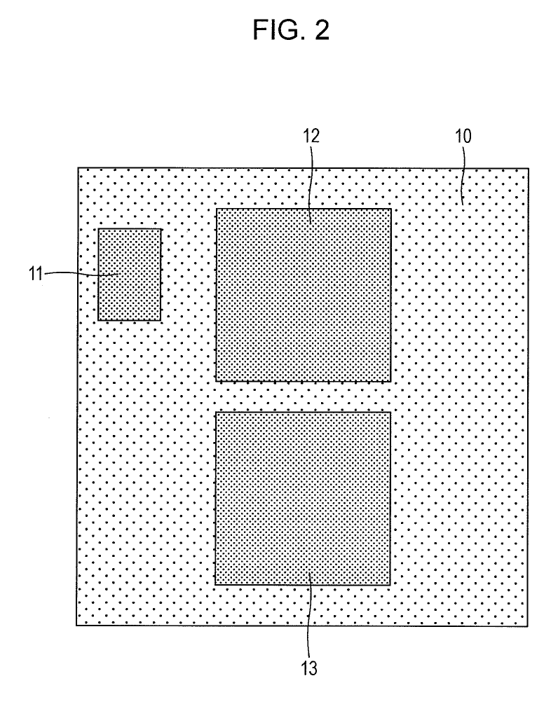

In FIG. 1, a semiconductor chip 10 is fixed on a lead frame main body 20 with a die attaching agent 30 such as solder. The semiconductor chip 10 may be an HEMT including a GaN-based material. FIG. 2 illustrates an exemplary top surface of a semiconductor chip. The semiconductor chip illustrated in FIG. 2 may be the semiconductor chip illustrated in FIG. 1. In FIG. 2, a gate electrode pad 11, a source electrode pad 12, and a drain electrode pad 13 which include a metal material such as Al, Au, or Cu are formed on a surface of a semiconductor chip 10.

The gate electrode pad 11 is coupled to a gate lead 21 with a bonding wire 41. The source electrode pad 12 is coupled to a source lead 22 with a bonding wire 42. The drain electrode pad 13 is coupled to a drain lead 23 with a bonding wire 43. The bonding wires 41, 42, and 43 may be metal lines and may include a metal material such as Al, Au, or Cu.

The bonding wire 41 is covered with a first resin portion 51 in a region extending from a coupling portion between the gate electrode pad 11 and the bonding wire 41 to a coupling portion between the gate lead 21 and the bonding wire 41. The bonding wire 42 is covered with a first resin portion 52 in a region extending from a coupling portion between the source electrode pad 12 and the bonding wire 42 to a coupling portion between the source lead 22 and the bonding wire 42. The bonding wire 43 is covered with a first resin portion 53 in a region extending from a coupling portion between the drain electrode pad 13 and the bonding wire 43 to a coupling portion between the drain lead 23 and the bonding wire 43. The first resin portions 51, 52, and 53 include a resin material such as polyimide. The first resin portions 51, 52, and 53 are formed by, for example, spraying the resin material. Therefore, deformation and the like of the bonding wires 41, 42, and 43 may be reduced. The moisture resistance of the first resin portions 51, 52, and 53 including a resin material such as polyimide is higher than those of molding resins.

The semiconductor chip 10, the bonding wires 41, 42, and 43 covered with the first resin portions 51, 52, and 53, respectively, the lead frame main body 20, a part of the gate lead 21, a part of the source lead 22, and a part of the drain lead 23 are covered with a second resin portion 60. The second resin portion 60 includes a molding resin and the like. A resin seal may be performed by a transfer molding method.

In the semiconductor device, after the bonding wires 41, 42, and 43 and the like are covered with the first resin portions 51, 52, and 53, respectively, the first resin portions are covered with the second resin portion 60. When the resin seal is performed by a transfer molding method or the like, deformation, disconnection, and the like of the bonding wires 41, 42, and 43 may be reduced because the bonding wires 41, 42, and 43 have been covered with the first resin portions 51, 52, and 53, respectively.

Resin materials such as a molding resin may not have sufficient moisture resistance. The first resin portions 51, 52, and 53 including a resin material having high moisture resistance, such as polyimide, are formed, thereby reducing intrusion of moisture from the outside. Oxidation or corrosion of Cu or the like, which is included in the bonding wires 41, 42, and 43, may be reduced.

As the metal lines, the bonding wires 41, 42, and 43 which are metal wires may be used. Alternatively, metal ribbons or the like may be used instead of the metal wires.

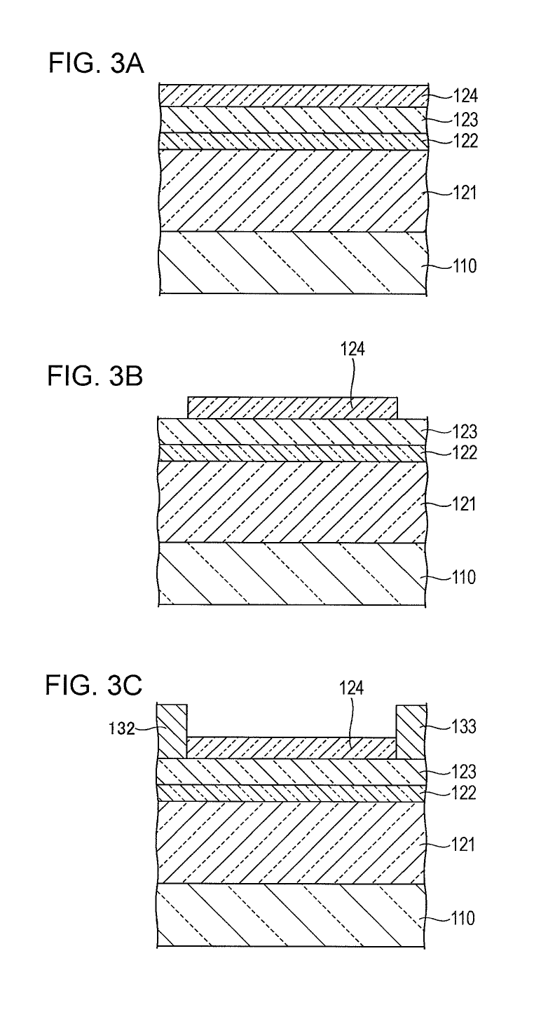

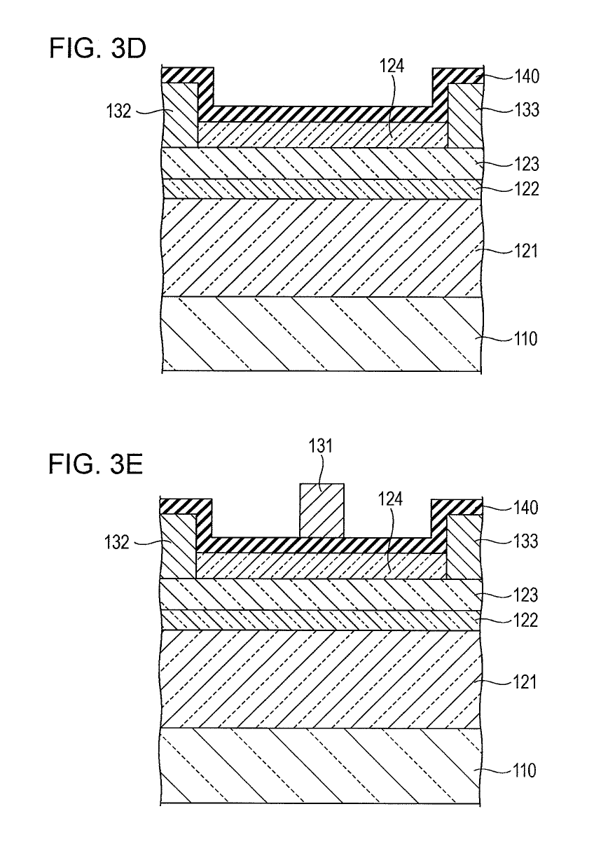

FIGS. 3A to 3E illustrate an exemplary method of manufacturing a semiconductor chip. The semiconductor chip illustrated in FIGS. 3A to 3E may be the semiconductor chip illustrated in FIG. 1 or 2.

As illustrated in FIG. 3A, a semiconductor layer including, for example, an electron transit layer 121, a spacer layer 122, an electron supply layer 123, and a cap layer 124 is formed on a substrate 110 by epitaxial growth such as metal-organic vapor phase epitaxy (MOVPE). The substrate 110 may include Si, SiC, sapphire (Al₂O₃), or the like. A buffer layer (not illustrated) for epitaxially growing the electron transit layer 121 and other layers is formed on the substrate 110. The buffer layer may be, for example, an undoped i-AlN layer having a thickness of 0.1 μm. The electron transit layer 121 may be an undoped i-GaN layer having a thickness of 3 μm. The spacer layer 122 may be an undoped i-AlGaN layer having a thickness of 5 nm. The electron supply layer 123 may be an n-Al_{0.25}Ga_{0.75}N layer having a thickness of 30 nm and doped with Si serving as an impurity element at a concentration of 5×10¹⁸ cm⁻³. The cap layer 124 may be an n-GaN layer having a thickness of 10 nm and doped with Si serving as an impurity element at a concentration of 5×10¹⁸ cm⁻³.

As illustrated in FIG. 3B, the cap layer 124 in regions where a source electrode 132 and a drain electrode 133 are to be formed is removed so that the electron supply layer 123 is exposed in the regions. For example, a photoresist is applied onto the surface of the cap layer 124. The photoresist is exposed by an exposure apparatus and then developed to form a resist pattern (not illustrated) having openings in the regions where the source electrode 132 and the drain electrode 133 are to be formed. The cap layer 124 in the openings of the resist pattern (not illustrated) is removed by dry etching such as reactive ion etching (RIE) using a chlorine-based gas. The resist pattern (not illustrated) is removed by an organic solvent or the like. Thus, the cap layer 124 is removed in the regions where the source electrode 132 and the drain electrode 133 are to be formed, and the electron supply layer 123 is exposed in the regions.

As illustrated in FIG. 3C, the source electrode 132 and the drain electrode 133 are formed in the regions where the electron supply layer 123 is exposed by the removal of the cap layer 124. For example, a photoresist is applied onto the surface on which the cap layer 124 is formed. The photoresist is exposed by an exposure apparatus and then developed to form a resist pattern (not illustrated) having openings in the regions where the source electrode 132 and the drain electrode 133 are to be formed. Metal films, for example, a Ta film having a thickness of about 20 nm and an Al film having a thickness of about 200 nm are formed over the entire surface by vacuum deposition or the like. The metal films deposited on the resist pattern are then removed by lift-off using an organic solvent. The source electrode 132 and drain electrode 133 are formed using the metal films in regions where the resist pattern is not formed. Since a deposited metal film, e.g., the Ta film, is in contact with the electron supply layer 123, ohmic contact is established between the source electrode 132 and the drain electrode 133 by performing heat treatment in a nitrogen atmosphere at a temperature in the range of 400° C. to 700° C., for example, at 550° C. When the ohmic contact is established without heat treatment, the heat treatment may not be conducted.

As illustrated in FIG. 3D, an insulating film 140 corresponding to a gate insulating film is formed on the cap layer 124. For example, the insulating film 140 may include aluminum oxide (Al₂O₃). For example, the insulating film 140 having a thickness of about 10 nm is deposited by atomic layer deposition (ALD) using trimethylaluminum (TMA) and pure water (H₂O) at a substrate temperature of 300° C.

As illustrated in FIG. 3E, a gate electrode 131 is formed in a certain region on the insulating film 140. For example, a photoresist is applied onto a surface on which the insulating film 140 is formed. The photoresist is exposed by an exposure apparatus and then developed to form a resist pattern (not illustrated) having an opening in the region where the gate electrode 131 is to be formed. Metal films, for example, a Ni film having a thickness of about 40 nm and a Au film having a thickness of about 400 nm are formed over the entire surface by vacuum deposition. The metal films deposited on the resist pattern are then removed by lift-off using an organic solvent. The gate electrode 131 is formed using the metal films in a region where the resist pattern is not formed. The Ni film, which is a metal film, is formed on the insulating film 140, and heat treatment or the like may then be performed as required.

A protective film or the like is formed. As illustrated in FIG. 2, a gate electrode pad 11 coupled to the gate electrode 131, a source electrode pad 12 coupled to the source electrode 132, and a drain electrode pad 13 coupled to the drain electrode 133 are formed. The gate electrode 131 may include the gate electrode pad 11, the source electrode 132 may include the source electrode pad 12, and the drain electrode 133 may include the drain electrode pad 13. Thus, a semiconductor chip 10 is formed.

A semiconductor chip 10 having the semiconductor layer including GaN or AlGaN may be formed. Alternatively, a semiconductor chip having the semiconductor layer including InAlN or InGaAlN may be formed. In an electronic device including a transistor that operates at a high voltage and other components, the semiconductor layer may include Si, GaAs, SiC, C, or the like.

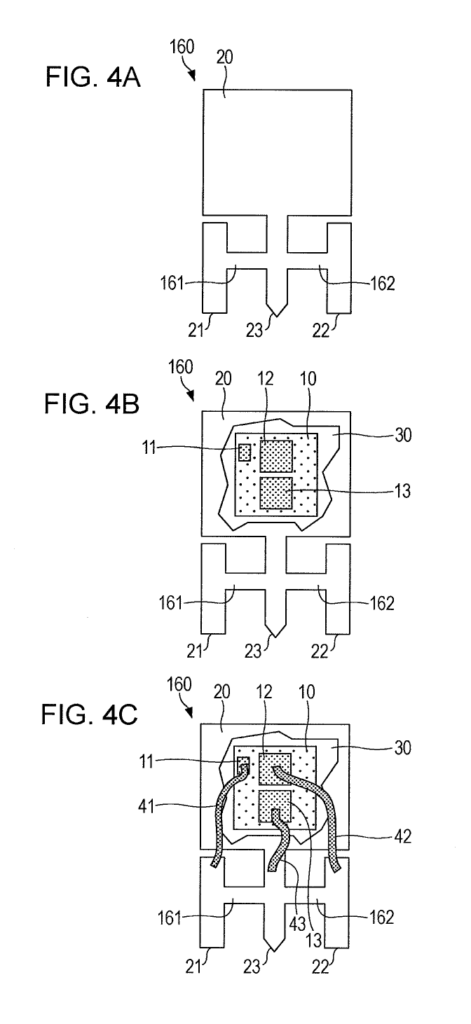

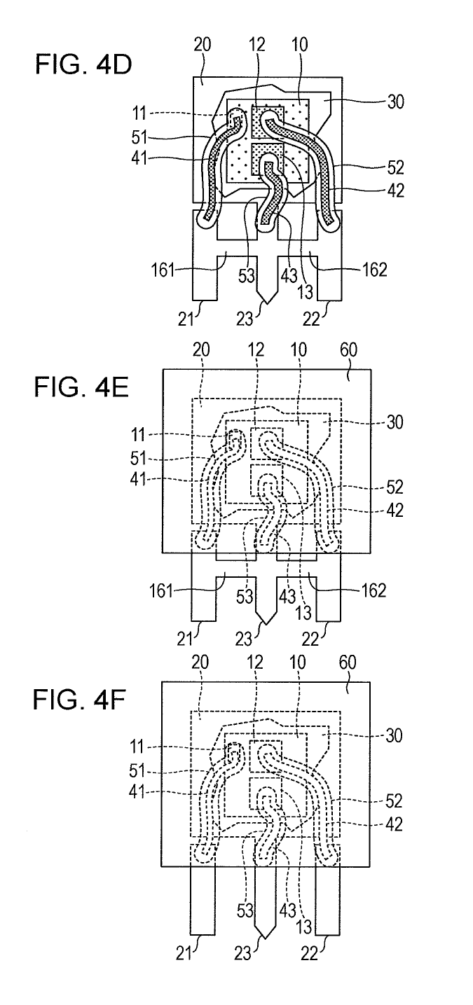

FIGS. 4A to 4F illustrate an exemplary method of manufacturing a semiconductor device.

As illustrated in FIG. 4A, a lead frame 160 is prepared by processing a metal sheet or the like. The lead frame 160 may include a conductive metal material including copper or the like. The lead frame 160 includes a lead frame main body 20 on which a semiconductor chip 10 is fixed, a gate lead 21, a source lead 22, and a drain lead 23. The drain lead 23 is coupled to the lead frame main body 20. The gate lead 21 is coupled to one side of the drain lead 23 with a joining portion 161 therebetween. The source lead 22 is coupled to the other side of the drain lead 23 with a joining portion 162 therebetween.

As illustrated in FIG. 4B, the semiconductor chip 10 is fixed to the lead frame main body 20 with a die attaching agent 30 such as solder.

As illustrated in FIG. 4C, connection is performed by wire bonding. A gate electrode pad 11 is coupled to the gate lead 21 with a bonding wire 41. A source electrode pad 12 is coupled to the source lead 22 with a bonding wire 42. A drain electrode pad 13 is coupled to the drain lead 23 with a bonding wire 43. The material included in the bonding wires 41, 42, and 43 may be substantially the same as or similar to the material included in the gate electrode pad 11, the source electrode pad 12, or the drain electrode pad 13.

As illustrated in FIG. 4D, the bonding wires 41, 42, and 43 are fixed by being covered with first resin portions 51, 52, and 53, respectively. For example, the bonding wire 41 is covered with the first resin portion 51 in a region extending from a coupling portion between the gate electrode pad 11 and the bonding wire 41 to a coupling portion between the gate lead 21 and the bonding wire 41. The bonding wire 42 is covered with the first resin portion 52 in a region extending from a coupling portion between the source electrode pad 12 and the bonding wire 42 to a coupling portion between the source lead 22 and the bonding wire 42. The bonding wire 43 is covered with the first resin portion 53 in a region extending from a coupling portion between the drain electrode pad 13 and the bonding wire 43 to a coupling portion between the drain lead 23 and the bonding wire 43. The material included in the first resin portions 51, 52, and 53 may be polyimide or the like. The first resin portions 51, 52, and 53 are formed by spraying a resin material such as polyimide using a shadow mask having openings in regions where the first resin portions 51, 52, and 53 are to be formed. Alternatively, the first resin portions 51, 52, and 53 may be formed by supplying a resin material such as polyimide using a dispenser or the like.

As illustrated in FIG. 4E, the semiconductor chip 10 is fixed by being covered with a second resin portion 60 together with a part of the lead frame 160. For example, the second resin portion 60 is formed by a transfer molding method. The second resin portion 60 may include a molding resin, and may include a material suitable for a high breakdown voltage. Properties of the second resin portion 60 may be different from those of the first resin portions 51, 52, and 53. The material of the first resin portions 51, 52, and 53 may be different from the material of the second resin portion 60.

As illustrated in FIG. 4F, the joining portion 161 coupling the drain lead 23 to the gate lead 21 is cut and removed. The joining portion 162 coupling the drain lead 23 to the source lead 22 is cut and removed. Thus, a semiconductor device is fabricated. The gate lead 21 and the source lead 22 may not be coupled to the lead frame main body 20, and may be fixed by a molding resin included in the second resin portion 60.

The second resin portion 60 may include a molding resin, and may include other materials etc.

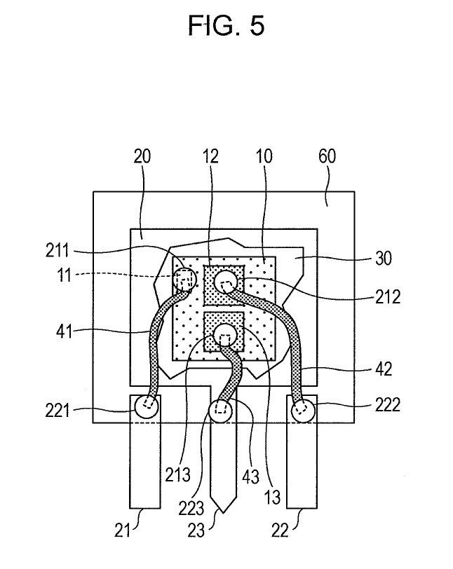

FIG. 5 illustrates an exemplary semiconductor device. The semiconductor device may include a semiconductor chip on which a discrete-packaged HEMT transistor is formed. The semiconductor chip may be the semiconductor chip 10 illustrated in FIG. 1. FIG. 5 illustrates a state where a part of a surface of a second resin portion 60 is removed.

A semiconductor chip 10 is fixed on a lead frame main body 20 with a die attaching agent 30 such as solder. The semiconductor chip 10 may be an HEMT including a GaN-based material.

A coupling portion between a gate electrode pad 11 and a bonding wire 41 is covered with a first resin portion 211. A coupling portion between a gate lead 21 and the bonding wire 41 is covered with a first resin portion 221. A coupling portion between a source electrode pad 12 and a bonding wire 42 is covered with a first resin portion 212. A coupling portion between a source lead 22 and the bonding wire 42 is covered with a first resin portion 222. A coupling portion between a drain electrode pad 13 and a bonding wire 43 is covered with a first resin portion 213. A coupling portion between a drain lead 23 and the bonding wire 43 is covered with a first resin portion 223. The first resin portions 211, 212, 213, 221, 222, and 223 include a resin material such as polyimide and are formed by, for example, spraying the resin material.

The whole semiconductor chip 10, first resin portions 211, 212, 213, 221, 222, and 223, bonding wires 41, 42, and 43, and lead frame main body 20 are covered with the second resin portion 60 and sealed. The second resin portion 60 may include a molding resin and the like, and a resin seal may be performed by a transfer molding method.

The first resin portions 211, 212, 213, 221, 222, and 223 are formed without deformation or disconnection of the bonding wires 41, 42, and 43. The coupling portions of the bonding wires 41, 42, and 43 are fixed by forming the first resin portions 211, 212, 213, 221, 222, and 223. The second resin portion 60 is formed by a transfer molding method or the like without detachment of the bonding wires 41, 42, and 43 from the corresponding electrode pads or leads, and the resin seal is performed. A highly reliable semiconductor device may be provided at a high yield.

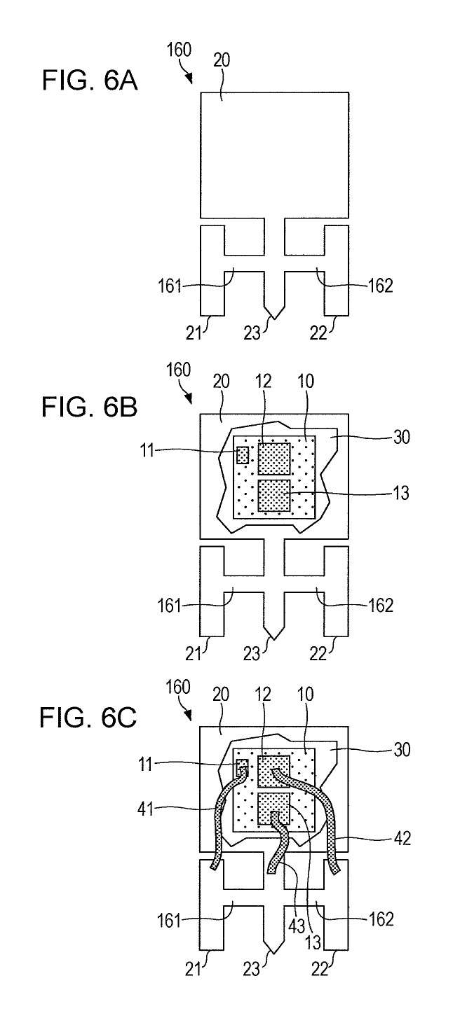

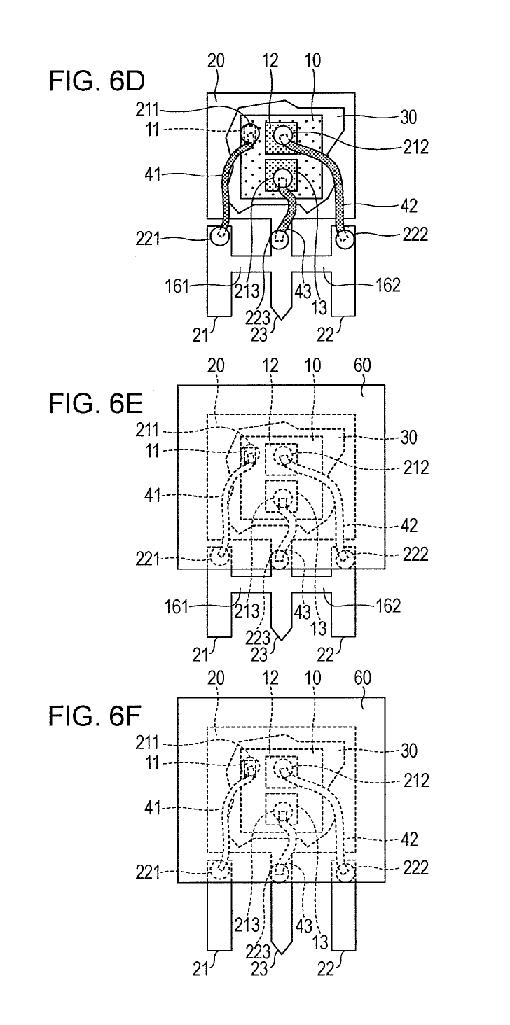

FIGS. 6A to 6F illustrate an exemplary method of manufacturing a semiconductor device.

As illustrated in FIG. 6A, a lead frame 160 is prepared by processing a metal sheet or the like. The lead frame 160 may include a conductive metal material containing copper or the like.

As illustrated in FIG. 6B, a semiconductor chip 10 is fixed to a lead frame main body 20 with a die attaching agent 30 such as solder.

As illustrated in FIG. 6C, coupling is performed by wire bonding. A gate electrode pad 11 is coupled to a gate lead 21 with a bonding wire 41. A source electrode pad 12 is coupled to a source lead 22 with a bonding wire 42. A drain electrode pad 13 is coupled to a drain lead 23 with a bonding wire 43.

As illustrated in FIG. 6D, coupling portions of the bonding wires 41, 42, and 43 are fixed by being covered with first resin portions 211, 212, 213, 221, 222, and 223. For example, the coupling portion between the gate electrode pad 11 and the bonding wire 41 is covered with the first resin portion 211. The coupling portion between the gate lead 21 and the bonding wire 41 is covered with the first resin portion 221. The coupling portion between the source electrode pad 12 and the bonding wire 42 is covered with the first resin portion 212. The coupling portion between the source lead 22 and the bonding wire 42 is covered with the first resin portion 222. The coupling portion between the drain electrode pad 13 and the bonding wire 43 is covered with the first resin portion 213. The coupling portion between the drain lead 23 and the bonding wire 43 is covered with the first resin portion 223. The material included in the first resin portions 211, 212, 213, 221, 222, and 223 may be a resin material such as polyimide. For example, the first resin portions are formed by spraying a resin material such as polyimide using a shadow mask having openings in regions where the first resin portions 211, 212, 213, 221, 222, and 223 are to be formed. Alternatively, the first resin portions 211, 212, 213, 221, 222, and 223 may be formed by supplying a resin material such as polyimide using a dispenser or the like.

As illustrated in FIG. 6E, the semiconductor chip 10 fixed on the lead frame 160 is fixed by being covered with a second resin portion 60 together with a part of the lead frame 160. For example, the semiconductor chip 10 and the part of the lead frame 160 are fixed by the second resin portion 60 formed by a transfer molding method. The second resin portion 60 may include a molding resin, and may include a material suitable for a high breakdown voltage. Properties of the second resin portion 60 may be different from those of the first resin portions 211, 212, 213, 221, 222, and 223. The material of the first resin portions 211, 212, 213, 221, 222, and 223 may be different from the material of the second resin portion 60.

As illustrated in FIG. 6F, a joining portion 161 coupling the drain lead 23 to the gate lead 21 is cut and removed. A joining portion 162 coupling the drain lead 23 to the source lead 22 is cut and removed. Thus, a semiconductor device is fabricated. The gate lead 21 and the source lead 22 may not be coupled to the lead frame main body 20, and may be fixed by the molding resin which is the second resin portion 60.

The semiconductor device is fabricated by the method illustrated in FIGS. 6A to 6F. The method for manufacturing the semiconductor chip 10 may be substantially the same as or similar to the method illustrated in FIGS. 3A to 3E.

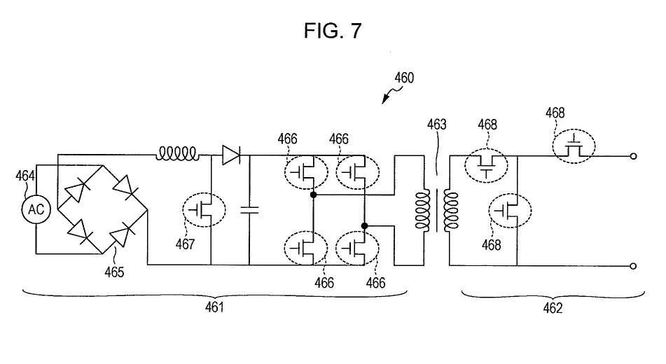

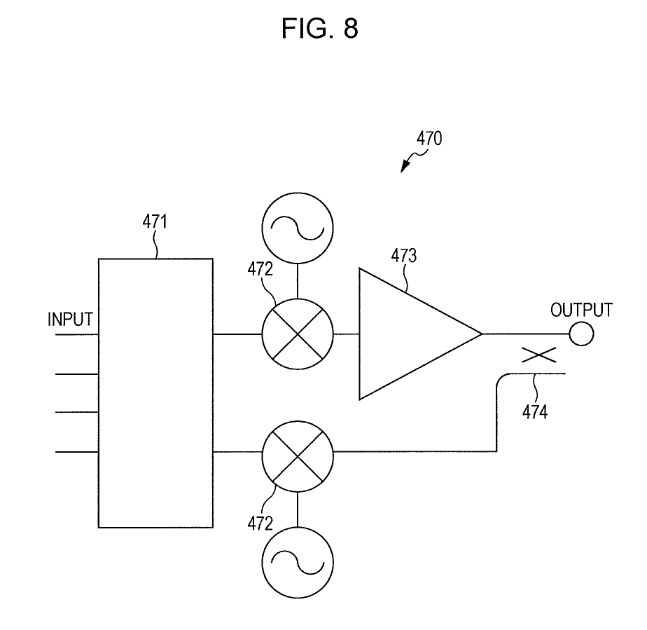

FIG. 7 illustrates an exemplary power supply circuit. FIG. 8 illustrates an exemplary high-frequency amplifier. The power supply circuit illustrated in FIG. 7 and the high-frequency amplifier illustrated in FIG. 8 may include the semiconductor device illustrated in FIG. 1 or 5.

A power supply circuit 460 illustrated in FIG. 7 includes a high-voltage primary side circuit 461, a low-voltage secondary side circuit 462, and a transformer 463 provided between the primary side circuit 461 and the secondary side circuit 462. The primary side circuit 461 includes an AC power supply 464, a bridge rectifier circuit 465, and a plurality of, for example, four switching elements 466, a switching element 467, etc. The secondary side circuit 462 includes a plurality of, for example, three switching elements 468. In FIG. 7, for example, the semiconductor device illustrated in FIG. 1 may be used as the switching elements 466 and 467 of the primary side circuit 461. The switching elements 466 and 467 of the primary side circuit 461 may each be a normally-off semiconductor device. The switching elements 468 used in the secondary side circuit 462 may each be a metal-insulator-semiconductor field-effect transistor (MISFET) including silicon.

A high-frequency amplifier 470 illustrated in FIG. 8 may be used in a power amplifier for a base station of mobile phones. The high-frequency amplifier 470 includes a digital pre-distortion circuit 471, mixers 472, a power amplifier 473, and a directional coupler 474. The digital pre-distortion circuit 471 compensates for non-linear distortion in an input signal. One of the mixers 472 mixes the input signal in which the non-linear distortion is compensated for with an alternating current signal. The power amplifier 473 amplifies the input signal mixed with the alternating current signal. In FIG. 8, the power amplifier 473 may include the semiconductor device illustrated in FIG. 1. The directional coupler 474 performs, for example, monitoring of an input signal and an output signal. For example, based on switching of a switch, the other mixer 472 may mix an output signal with an alternating current signal and transmit the mixed signal to the digital pre-distortion circuit 471.

Example embodiments of the present invention have now been described in accordance with the above advantages. It will be appreciated that these examples are merely illustrative of the invention. Many variations and modifications will be apparent to those skilled in the art.

1. A semiconductor device comprising:
a semiconductor chip having an electrode;
a lead corresponding to the electrode;
a metal line coupling the electrode to the lead;
a first resin portion covering a coupling portion between the metal line and the electrode and a coupling portion between the metal line and the lead; and
a second resin portion covering the metal line, the first resin portion, and the semiconductor chip.

2. The semiconductor device according to claim 1, wherein the metal line is covered with the first resin portion.

3. The semiconductor device according to claim 1, wherein the metal line is a bonding wire or a metal ribbon.

4. The semiconductor device according to claim 3, wherein the metal line includes at least one material selected from the group consisting of Al, Au, and Cu.

5. The semiconductor device according to claim 1, wherein the electrode is coupled to an electrode of an electronic device included in the semiconductor chip.

6. The semiconductor device according to claim 1, wherein the semiconductor chip includes an electronic device having a semiconductor layer including a nitride semiconductor.

7. The semiconductor device according to claim 6, wherein the nitride semiconductor includes at least one of a first group and a second, the first group including GaN and AlGaN, and the second group including InAlN and InGaAlN.

8. The semiconductor device according to claim 6, wherein the electronic device is a high electron mobility transistor (HEMT).

9. The semiconductor device according to claim 1,
wherein the electrode corresponds to a plurality of the electrodes and the lead corresponds to a plurality of the leads, and
each of the plurality of electrodes is coupled to the corresponding lead included in the plurality of leads by the metal line.

10. The semiconductor device according to claim 1, wherein a resin material included in the first resin portion is substantially different from a resin material included in the second resin portion.

11. The semiconductor device according to claim 1, wherein the first resin portion includes polyimide.

12. The semiconductor device according to claim 1, wherein the second resin portion includes a molding resin.

13. A method of manufacturing a semiconductor device comprising:
arranging a semiconductor chip on a lead frame;
coupling an electrode included in the semiconductor chip to a lead included in the lead frame via a metal line;
covering a coupling portion between the metal line and the electrode and a coupling portion between the metal line and the lead with a first resin portion; and
covering the metal line, the first resin portion, the semiconductor chip, and a part of the lead with a second resin portion.

14. The method according to claim 13, wherein the metal line is covered with the first resin portion.

15. The method according to claim 13, wherein the metal line is a bonding wire or a metal ribbon.

16. The method according to claim 13, further comprising,
supplying a material included in the first resin portion with a spray or a dispenser.

17. The method according to claim 13, further comprising;
arranging a mask having an opening in a region where the first resin portion is to be formed; and
spraying a material contained in the first resin portion on the mask so as to form the first resin portion in the region of the opening.

18. The method according to claim 13, wherein the first resin portion includes polyimide.

19. An electronic circuit comprising:
a semiconductor device includes:
a semiconductor chip having an electrode;
a lead corresponding to the electrode;
a metal line coupling the electrode to the lead;
a first resin portion covering at least a coupling portion between the metal line and the electrode and a coupling portion between the metal line and the lead; and
a second resin portion covering the metal line, the first resin portion, and the semiconductor chip.

20. The electronic circuit according to claim 19, wherein the electronic circuit is one of a power supply circuit and a high-frequency amplifier.
